(19) United States
(12) Patent Application Publication
(10) Pub. No.: US 2008/0093047 A1
(43) Pub. Date: Apr. 24, 2008

(54) CASTING MOLDS COATED FOR SURFACE ENHANCEMENT AND METHODS OF MAKING

(75) Inventors: Xinqing Ma, Willington, CT (US); T. Danny Xiao, Willington, CT (US)

Correspondence Address: CANTOR COLBURN, LLP, 20 Church Street, 22nd Floor, Hartford, CT, 06103, US

(73) Assignee: Inframat Corporation, Farmington, CT (US)

(21) Appl. No.: 11/874,725

(22) Filed: Oct. 18, 2007

Related U.S. Application Data
(60) Provisional application No. 60/862,040, filed on Oct. 18, 2006.

(51) Int. Cl. B22D 23/00; B05D 1/08; B23K 31/00; C25D 7/00; C23C 14/34; B22C 3/00

(52) U.S. Cl. 164/72; 204/192.1; 205/149; 228/101; 249/114.1; 427/135; 427/446

(57) ABSTRACT

Disclosed herein are molds coated for surface enhancement, methods of making the molds, and methods of casting using such molds. In one embodiment, a mold comprises: a mold member comprising copper; and a coating disposed on at least a portion of a surface of the mold member, wherein the coating has a coefficient of thermal expansion of about 10×10⁻⁶/° C. to about 16.5×10⁻⁶/° C. and a Vickers Hardness Number of greater than about 500 and less than about 1200 at a temperature of less than or equal to about 600° C.

### CROSS REFERENCE TO RELATED APPLICATION

This application claims the benefit of U.S. Provisional Patent Application No. 60/862,040 filed Oct. 18, 2006, which is incorporated by reference herein in its entirety.

### TECHNICAL FIELD

The present disclosure relates to copper-based molds with enhanced surface properties for use in continuous or semi-continuous casting processes. It more specifically relates to molds having a surface at least partially coated with a coating having a thermal expansion coefficient equivalent to or slightly lower than that of copper and a Vickers Hardness Number and corrosion resistance significantly higher than copper.

### BACKGROUND

Copper-based molds are currently used in continuous or semi-continuous casting processes. Current molds can include a single copper tube or an assembly of several copper plates. Casting processes can involve contacting the interior surface of a mold directly with a hot molten metal or alloy that solidifies to form a cast strand comprising a self-supporting surface layer or shell around a residual melt (in the contact surface between the copper mold and the liquid metal). The interior surface can be finely polished and even mirror finished to improve its lubricity and reduce the friction between it and the molten material. The exterior surface of the mold can include internal cavities or channels for the flow of cooling water to maintain heat transfer from the molten material to the mold.

The service life of a mold can primarily depend on the working conditions. The mold can often fail due to interior surface damage such as surface cracking, mold deformation, scratching, casting folds or lateral cracks in the thin wall strand, erosion, brittleness, copper oxidation, and so forth. Surface cracking can be caused by high temperature creep of the copper substrate and the presence of thermal stress and mechanical load during casting. Mold deformation or buckling can be caused by copper inelastic deformation, improper installation or positioning of the copper plates, and/or temperature fluctuations in the molten metal. Non-uniform heat flow or temperature distributions can also lead to cracking and deformation of the mold and can also introduce casting folds or lateral cracks in the thin wall strand. Mold erosion can be caused by the direct contact and relative movement of the mold with the molten material, heat protective mineral additives, and/or the solidified layer or shell of strand. The erosion damage can often be uneven and can be more severe at the mold exit and the mold corners and on the narrow side plates. Brittleness of the mold can be caused by the interdiffusion of Zn, S, Cd, and F from the molten material into the copper-containing mold, resulting in the formation of brittle compounds such as bronze. Moreover, the diffusion of Cu into the molten material can cause contamination problems. Finally, copper near the top section of the mold having direct contact with the molten material can undergo oxidation at working temperatures of about 400° C. to about 600° C.

Today, demands for cast steel have increased to levels where the service life of copper-based molds can be about two to four weeks (about 10,000 to 15,000 meters of strand) in a continuous steel casting process. The copper consumption for the production of one-ton steel is about 0.03 to about 0.05 kg. Unfortunately, the costs associated with the replacement of the molds and the downtime needed for this replacement can be very high.

### BRIEF SUMMARY

Disclosed herein are molds coated for surface enhancement, methods of making the molds, and methods of casting using such molds. In one embodiment, a mold comprises: a mold member comprising copper; and a coating disposed on at least a portion of a surface of the mold member, wherein the coating has a coefficient of thermal expansion (CTE) of about 10×10⁻⁶/° C. to about 16.5×10⁻⁶/° C. and a Vickers Hardness Number of greater than about 500 and less than about 1200 at a temperature of less than or equal to about 600° C.

In another embodiment, a method of forming a coating on a surface of a mold comprises: disposing a coating on at least a portion of a surface of a mold comprising copper, the coating having a coefficient of thermal expansion of about 10×10⁻⁶/° C. to about 16.5×10⁻⁶/° C. and a Vickers Hardness Number of greater than about 500 and less than about 1200 at a temperature of less than or equal to about 600° C.

In yet another embodiment, a method of casting a molten material comprises: disposing a molten material in a mold comprising copper, wherein an interior surface of the mold is at least partially coated with a coating having a coefficient of thermal expansion of about 10×10⁻⁶/° C. to about 16×10⁻⁶/° C. and a Vickers Hardness Number of greater than about 500 and less than about 1200 at a temperature of less than or equal to about 600° C.

The above described and other features are exemplified by the following detailed description and figures.

### BRIEF DESCRIPTION OF THE DRAWINGS

Referring now to the figures, which are exemplary embodiments and wherein like elements are numbered alike:

FIG. 1 schematically illustrates a copper-based mold comprising a rectangular tube or an assembly of four plates;

FIG. 2 schematically illustrates a copper mold plate having a coating disposed on an interior surface of the plate;

FIGS. 3(a)-3(c) schematically illustrate three embodiments of the interior surface coating of the mold plate from FIG. 2;

FIGS. 4(a) and 4(b) schematically illustrate a mold having a composite coating disposed on a surface of the mold, wherein the coating comprises a metallic matrix and particles dispersed in the metallic matrix; and

FIG. 5 schematically illustrates a copper mold plate having three coatings of different compositions disposed oil three respective sections of the mold plate according to the surface property requirements for each section.

FIGS. 6(a)-6(c) schematically illustrate three embodiments of a copper mold plate coated in three different ways with variable coating thicknesses corresponding to respective sections of the mold plate;

FIG. 7 depicts a flow diagram illustrating an embodiment of the process for producing the coated molds; and

FIG. 8 depicts an optical micrograph of a copper-based mold having a coating comprising a bondcoat layer and a topcoat layer.

### DETAILED DESCRIPTION

Copper-based molds with enhanced surface properties and methods of making and using the same are described. In particular the molds include a mold member and a coating disposed on at least a portion of a surface of the mold member for enhancing the surface properties of the mold. The surface coating can be designed based on achieving physical and mechanical property matches between the coating materials and the copper-based mold. For example, the coating can have a coefficient of thermal expansion (CTE) equivalent to or slightly less than that of copper (i.e. about 10×10⁻⁶/° C. to about 16.5×10⁻⁶/° C.) and a Vickers Hardiness Number (HV) significantly greater than that of copper (i.e., greater than about 500 and less than about 1200) at a mold surface temperature of less than or equal to about 600° C. This temperature is based on what the mold can be exposed to during a continuous or semi-continuous casting process in a steel mill. The coating can also have higher corrosion resistance, erosion resistance (including sliding wear resistance), and/or higher tensile strength than does copper. The coating can also be capable of promoting uniform heat flow and can act as an inter-diffusion barrier that prevents migration of the copper out of the mold and adjacent materials into the mold. Other desirable properties of the coating include a relatively high thermal conductivity, a relatively high temperature stability, and a relatively high anti-sticking capability. Enhancing the interior surface of a mold in this manner can significantly increase the service lifetime of the mold.

As used herein, the term “mold” refers to any structure used to form a material positioned in an interior of the mold into a desired shape that remains after the material is removed from the mold. Examples of molds include but are not limited to casting molds, dies, inserts, and the like utilized in casting, molding, or extrusion processes. Also, the term “copper” refers to any metallic composition comprising copper such as pure copper, copper alloys and the like. It is understood that the coating design can be adjusted for other types of non-copper containing molds as well.

Turning now to the figures, FIG. 1 illustrates an exemplary embodiment of a casting mold 10 comprising copper. The casting mold 10 can be in the form of a single tube or an assembly of copper plates. It can include a support frame 40 and an interior surface 20 that can contact a molten material and a solidified strand moving through the mold 10 during a casting process. The mold 10 can also include an outer cooling surface 30 having channels for the flow of a coolant. The interior surface 20 can be subjected to severe service conditions during the casting process such as surface temperatures over 500° C., high-frequency vibration of the support frame 40, a large thermal gradient between the interior surface 20 and the cooling surface 30, and severe erosion and/or wear of the interior surface 20 in the presence of the molten material/strand and solid mineral additives. Therefore, it is desirable to modify the interior surface 20 by adding a coating thereon to enhance its properties.

One consideration for the surface coating design is based on matching the CTE's of the copper-based mold and the coating materials. Copper has a high CTE of about 16.5×10⁻⁶/° C. Alloys such as certain Fe-based alloys, Ni-based alloys, and Co-based alloys have CTE's slightly lower than that of copper (i.e., about 9×10⁻⁶/° C. to about 14×10⁻⁶/° C.) and are therefore exemplary candidates as coating materials from the viewpoint of a coefficient of thermal expansion match.

Another consideration for the surface coating design is based on the hardness of the coating materials at application temperatures. The hardness of a material can be related to its mechanical properties such as wear resistance and creep strength. The Vickers Hardness Number (HV) values of some materials that might serve as mold coating materials are given in Table I below. At room temperature (R.T.), all of the materials shown in Table I (except copper) have much higher hardness values than copper. However, at 500° C., the plated Cr, Ni—P, Ni—Co, and Fe—Ni materials exhibit a significant reduction in hardness values, whereas the other alloys (e.g., other Ni-based alloys and Co-based alloys) and WC/Co maintain high hardness values at the high temperature. Such alloys are therefore exemplary candidates as coating materials from the viewpoint of hardness.

TABLE 1

| | Materials | | | | | |
|---|---|---|---|---|---|---|
| Hard- | | | | Plated | | |
| ness | | Plated | | Ni—Co, | Other | |
| (HV) | Cu | Ni—P | Plated Cr | Fe—Ni | Alloys | WC/Co |
| R.T. | ~100 | ~400- | ~900-1000 | ~400-500 | ~650-750 | ~900-1200 |
| | | 600 | | | | |
| 500° C. | <100 | ~100 | ~100-150 | ~300-400 | ~650-750 | ~900-1200 |

Additional consideration for the surface coating design are based on the corrosion and erosion resistances (including sliding wear resistance) of the coating materials. Corrosion of the mold surface can be caused by, e.g., oxidation and/or sulfidation of the surface. Table 2 illustrates the corrosion resistance of various coating materials. The corrosion resistance of copper is relatively low. Of the materials shown in Table 2, only the other alloys (e.g., other Ni-based alloys and Co-based alloys) and WC/Co have high corrosion resistance, making them exemplary candidates as coating materials.

TABLE 2

| | Materials | | | | | |
|---|---|---|---|---|---|---|
| Corrosion | | Plated | Plated | Plated | Other | WC/ |
| Resistance | Cu | Ni—P | Cr | Ni—Co, Fe—Ni | Alloys | Co |
| Rate | Low | Low | Medium | Low | High | High |

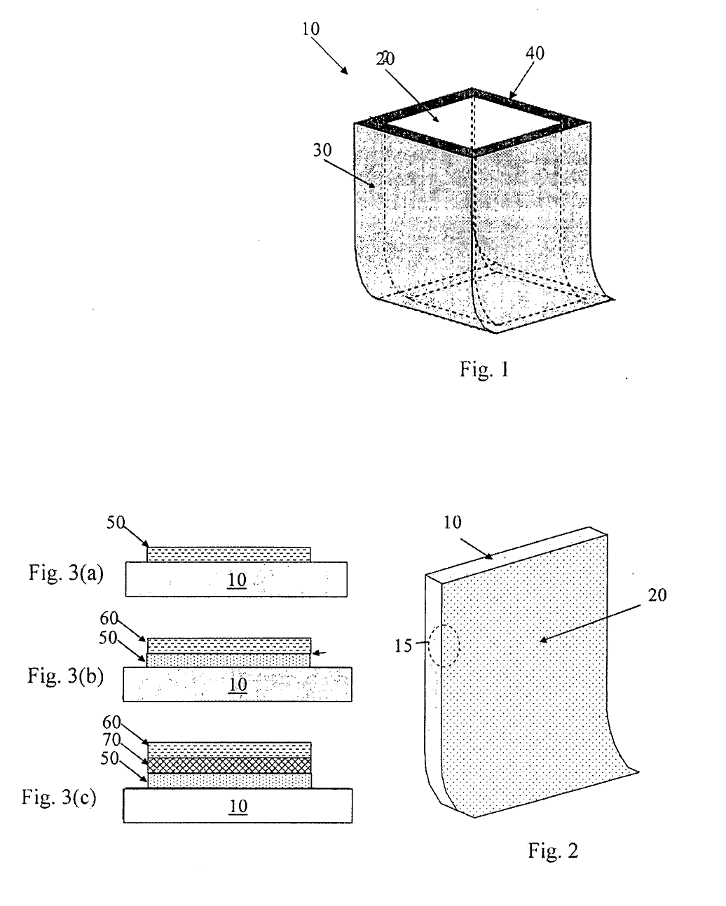

Turning now to FIG. 2, one of the plates of the copper-based mold 10 from FIG. 1 having a coating on its interior surface 20 is depicted. Three embodiments of a cross-section 15 of the mold 10 are illustrated in FIGS. 3(a)-3(c). In FIG. 3(a), a single-layered coating 50 is disposed on the interior surface of the mold 10. The coating 50 can have a CTRE near that of copper and a higher hardness than copper. In particular, the coating can have a CTE of about 10×10⁻⁶/° C. to about 14×10⁻⁶/° C. and a HV of greater than about 500 and less than about 1200 at a temperature of less than or equal to about 600° C. Examples of coating materials having these properties include but are not limited to certain Fe-based alloys, Co-based alloys, Ni-based alloys, and combinations comprising at least one of the foregoing. The amount of Fe, Co, or Ni present in the alloy can be about 70% by total weight of the alloy. Specific examples include Fe—Cr, Co—Cr, Ni—Cr, Ni—Al, Fe—Al, FeCrAl. NiCrAl, NiCrMo, NiCrSiB, NiCrAlY, CoCrAlY, and combinations comprising at least one of the foregoing.

Alternatively, the coating 50 can have a higher hardness and a higher corrosion resistance than does copper but not a CTE near that of copper at a temperature less than or equal to about 600° C. Examples of coating materials having these properties include but are not limited to a WC—Co alloy, a WC—CoCr alloy, a Ni—Cr₂C₃ alloy, a NiCr—Cr₂C₃ alloy, and combinations comprising at least one of the foregoing.

In FIG. 3(b), a double-layered coating is disposed on an interior surface of the mold 10 that includes a bondcoat layer 50 and a topcoat layer 60. The bondcoat layer 50 can act as a transitional buffer layer to accommodate thermal stress and mechanical loads at the interface of the mold surface/bondcoat layer. It can also act as a diffusion barrier to eliminate the outward diffusion of copper into the coating. The topcoat layer 60 can serve to protect the mold surface from corrosion, wear, and erosion damages. The bondcoat layer 50 can have a CTE near that of copper and a HV slightly higher than copper. The topcoat layer 60 can have a CTE near that of the bondcoat layer 50 and a HV higher than that of the bondcoat layer 50.

In another embodiment, a graded compositional or multi-layered coating can be disposed on an interior surface of the mold 10. The HV, the creep strength, the corrosion resistance, the erosion resistance, and/or the wear resistance of a coating comprising a graded composition can increase with distance from the surface. Similarly, the HV, the creep strength, the corrosion resistance, the erosion resistance, and/or the wear resistance of a coating comprising two or more layers can increase from one layer to the next in a direction away from the surface. For example, as shown in FIG. 3(c), the coating can include at least a bondcoat layer 50, a topcoat layer 60, and an intermediate layer 70. The extra layer 70 can act as a transitional layer having a CTE and a HV between those of the bondcoat layer 50 and the topcoat layer 60. The intermediate layer 70 can be a single composition layer, a multi-composition layer, or a graded composition layer. It can comprise a blend of the materials in the bondcoat layer 50 and the topcoat layer 60, or it can include other compositions that meet the selection criteria.

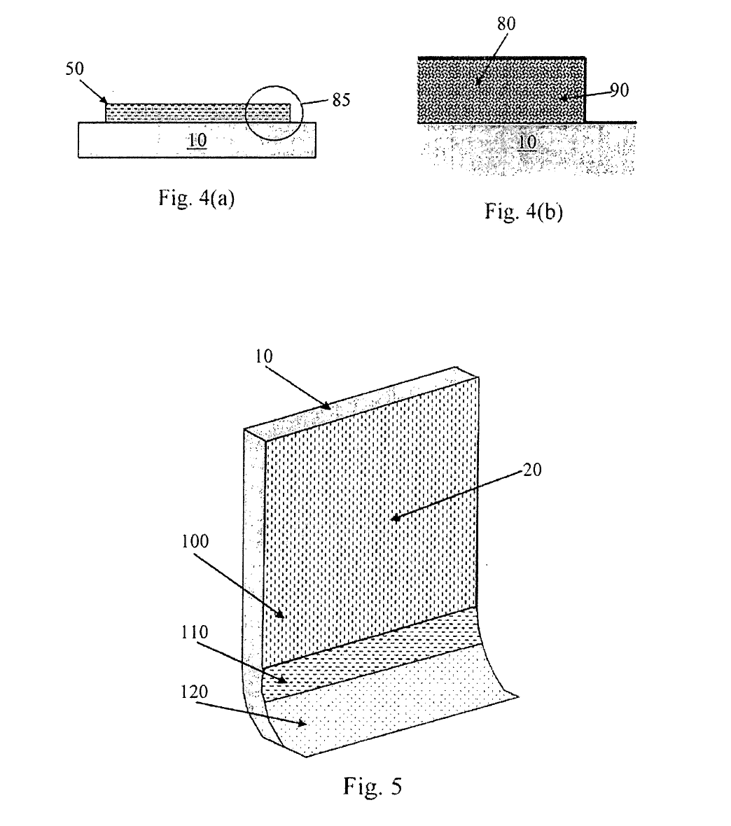

FIGS. 4(a) and 4(b) illustrate another embodiment of the coatings shown in FIGS. 3(a)-3(c) such as the topcoat layer 50. FIG. 4(b) specifically depicts section 85 of FIG. 4(a) in more detail. As shown, the coating 50 can include particles 80 (e.g., superfine particles and/or nanoparticles) distributed throughout a metallic matrix 90. As used herein, the term “metallic” refers to a material primarily comprising metal such as a pure metal or an alloy comprising more than one metal. The metallic matrix 90 can include, for example, Fe, Ni, Co, Co—Fe, Co—Ni, Co—B, Co—P, Fe—Ni, Ni—Cr, NiCrAlY, NiCrBSi, or a combination comprising at least one of the foregoing. The volume percentage of the dispersion particles present in the matrix can be about 1% to about 70%, more specifically about 10% to about 50%, by total volume of the coating. The coating can have, for example, a thickness of about 50 micrometers (microns) to about 3.0 millimeters (mm), more specifically about 100 microns to about 1.0 mm, and even more specifically about 100 microns to about 500 microns. As used herein, the term “superfine particles” refers to particles having a grain size of greater than about 100 nanometers (nm) and less than about 1 micron. Also, the term “nanoparticles” refers to particles having a grain size of less than about 100 nm. These coating thicknesses and particles sizes can also be applied to the coatings described in previous embodiments.

The addition of the particles 80 is also expected to bring an effect of dispersion strengthening to the matrix 90. The particles 80 can have a higher thermal conductivity, a higher lubricity, and/or a higher hardness than that of the matrix 90. For example, the particles 80 can include a lubricating additive, a thermally conductive additive, a hard additive, or a combination comprising at least one of the foregoing additives. The addition of thermally conductive additives is expected to improve heat flow uniformity and cooling efficiency, and the addition of lubricating additives and hard additives is expected to improve surface resistance to erosion and sticking. Examples of suitable lubricating additives include but are not limited to BN, MoSi₂, FeS, CaF₂, graphite, B₄C, and combinations comprising at least one of the foregoing. Examples of suitable thermally conductive additives include but are not limited to WC, TiN, AlN, Si₃N₄, and combinations comprising at least one of the foregoing. Examples of suitable hard additives include but are not limited to WC, Cr₂C₃, TiC, SiC, TiB₂, ZrB₂, and combinations comprising at least one of the foregoing.

FIG. 5 illustrates another embodiment of a plate of a copper-based mold 10. The top, middle, and bottom (exit) sections 100, 110, and 120, respectively, of the interior surface 20 of the plate are coated with different compositional coatings. More severe damage to the mold surface is expected to occur in the middle and bottom exit sections 10 and 120. By applying more corrosion and/or erosion resistant coatings at these two sections, the lifetime of the mold 10 can be extended. Similarly, for a rectangular mold, severe erosion damage is expected on the two narrow sides, and less erosion damage is expected on the two wide sides. Therefore, different coatings can be applied to the narrow sides and the wide sides to achieve an equivalent longer lifetime for both narrow and wide sides. Further, the edges and the corners of a mold can be enhanced by applying a different coating on their surfaces than applied to the rest of the mold. In summary, the lifetime of a copper-based mold can be significantly increased by defining damage severity and locations and applying different coatings accordingly.

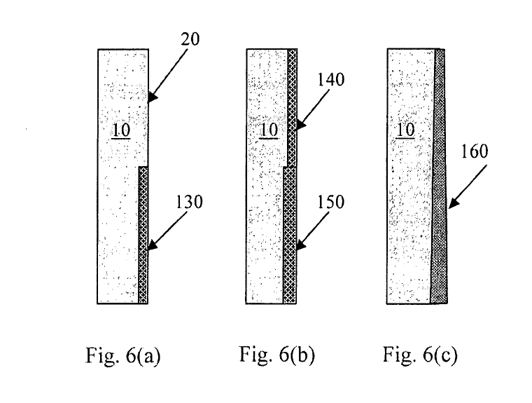

FIGS. 6(a)-6(c) illustrate three additional embodiments of a plate of a copper-based mold 10. In FIG. 6(a), a coating 130 only is disposed on a lower section of the interior surface of the plate. Since the upper section of the plate does not include a coating, it can have a more efficient heat transfer because of its direct contact with the molten material. The coated lower section of the plate can provide high erosion and/or corrosion resistance against the solidifying strand. In FIG. 6(b), the upper and lower sections 140 and 150, respectively, of the mold 10 can be coated with coatings of different thicknesses. More severe thermal distortion and less wear to the plate can occur in the upper section of the plate. In contrast, more severe wear and corrosion and less thermal strain to the plate can occur in the lower section of the plate. Therefore, applying coatings of different thicknesses to these two sections can compromise the different property requirements. Similarly, in FIG. 6(c), the coating thickness increases gradiently from the upper section to the lower section of the plate. The graded thickness profile can increase coating integrity, structural continuity, and property transition. Therefore, the coating can better accommodate thermal stress, mechanical loads, and material removal due to wear and erosion.

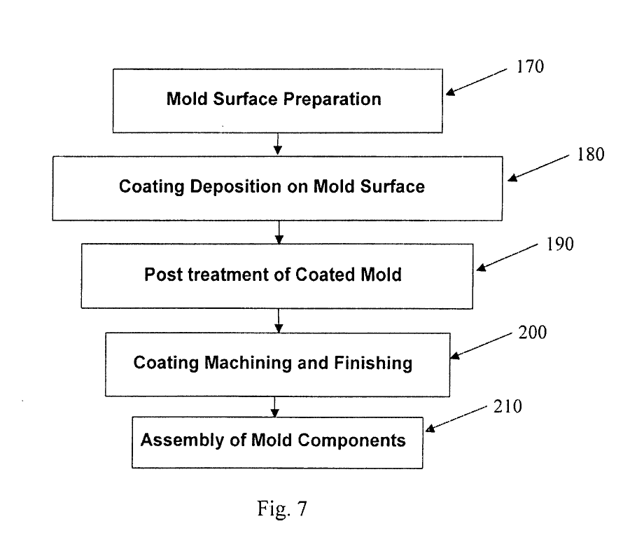

The foregoing copper-based mold can be made in accordance with the exemplary process illustrated in FIG. 7. The process begins with preparation of the mold surface by de-greasing in an organic solvent such as acetone or ethanol, drying with hot or compressed air, and sand blasting for removing oxides and producing a desired roughness (step 170). Next, a coating can be disposed on at least a portion of a surface of the mold (step 180). Examples of suitable methods for forming the surface coating include but are not limited to thermal spraying, overlay welding, cladding, physical vapor deposition (PVD), and electroplating. Optimized process parameters can be employed to apply the surface coating. The coated mold can then be exposed to post treatments to increase coating density, close open pores and cracks, and increase bond strength between the coating and the mold (step 190). The post treatments can include heat treatment, re-fusing/melting, sintering, and hot isostatic pressing (HIP). Subsequently, the coating can be machined to a desired thickness, shape, and surface finishing by cutting, grinding, honing, lapping, and/or polishing (step 200). Finally, mold components, including cooling tanks, support frames, and a coated tube or plate assembly can be assembled together for the casting operation (step 210).

In an exemplary embodiment, thermal spraying technology can be utilized to form the surface coating in step 180. Examples of thermal spray processes include electric arc spray, combustion flame spray, detonation spray, plasma spray, high velocity oxygen (air) fuel (HVOF) spray, cold spray, and the like. Plasma spraying and HVOF spraying can advantageously produce high quality coatings having high adhesion and cohesion strengths, high density, and less oxide inclusions. These processes involve forming a feedstock comprising solid particles or an agglomeration of particles (e.g., superfine particles and/or nanoparticles) and feeding the feedstock into a high velocity flame, such as a plasma arc or HVOF flame, generated by the ionization or combustion of a mixture of gases, respectively. As a result, the feedstock melts and impacts on the target substrate to form a coating thereon. Modified plasma spray and HVOF spray processes can also be used to form the coating. For example, plasma spraying and HVOF spraying using liquid suspensions comprising fine particles of INCONEL® 625 NiCrMo alloy and self-flux NiCrSiB alloy (commercially available from powder vendors such as Praxair Surface Technology) can produce highly bonded and fine-grained coatings as shown in the examples below. Additional disclosure related to modified HVOF spray processes can be found in concurrently owned U.S. Patent Application Ser. No. 60/826,663 to Ma et al., filed on Sep. 22, 2006, which is incorporated by reference herein. With thermal spraying techniques, coatings of large thicknesses (e.g., greater than 1 mm) can be built at a relatively high deposition rate. In principle, thermal spraying has no limit in the dimension of the coated area and is therefore suitable for coating large molds.

The thermally sprayed coatings can be exposed to post treatments as described above in step 190. For example, a thermally sprayed NiCrSiB self-fluxing alloy coating can be refused at a temperature of about 1000° C. in a vacuum or inert gas filled chamber. The refusing treatment can result in a fully dense coating and a strong metallurgical bond between the coating and the substrate. Also, open pores and micron-sized cracks in the thermally sprayed coatings can be sealed with suitable sealants, such as Al, Cr phosphates, colloided SiO₂ and sodium silicate, applied to the pores and cracks in solution form. After the evaporation or thermal decomposition of the sealant solution at a high temperature, the sealant material most likely will fill the pores and cracks. The corrosion resistance, strength, and likely the anti-sticking property of the sealant can be improved. Further, as indicated in step 200, the thermally sprayed coating can be machined to a desired surface roughness, configuration, and coating thickness by, e.g., cutting, grinding, honing, and polishing.

In another exemplary embodiment, PVD can be utilized to form the surface coating in step 180. PVD processes such as sputtering can produce high quality coatings having a high bonding strength, a high density, and a smooth surface. With a multi-source/target setup, PVD can readily produce multi-layered or graded coating structures. However, technically and economically, the use of PVD can be limited by a small processing chamber relative to the dimension of the mold to be coated and low coating thickening rates.

In still another exemplary embodiment, the surface coating can be fortified in step 180 by composite electroplating. In comparison to a current electroplating process, a composite electroplating process is capable of incorporating superfine particles and nanoparticles (metal, alloy, ceramic, or metal-ceramic composite particles) into a metallic matrix layer to form coatings like those shown in FIGS. 4(a) and 4(b). Additional disclosure related to composite electroplating can be found in concurrently owned U.S. patent application Ser. No. 11/858,750 to Xiao et al., filed on Sep. 20, 2007, which is incorporated by reference herein.

The invention is further illustrated by the following non-limiting examples.

### EXAMPLES

### Example 1

In this example, HVOF spraying was used to deposit a single layered coating of INCONEL® 625 particles onto a copper substrate. HVOF process parameters for the coating are given below:

| Coating composition: | Ni—22Cr—9Mo—3.5(Nb + Ta), wt. % | |
|---|---|---|
| HVOF system: | DJ-2700 (commercially available from | |
| | Sulzer-Metco, US) | |
| Process parameters: | Oxygen pressure/flow: | 150 pounds per |
| | | square inch (psi)/ |
| | | 24 standard cubic foot |
| | | per hour (scfh) |
| | Fuel pressure/flow: | 100 psi/44 scfh |
| | Air pressure/flow: | 105 psi/48 scfh |
| | Distance: | 11 inches (″) |
| | Feed rate: | 5 pounds/hour (lb/h) |

The coating properties are listed below:

### Coating hardness (HV at 300 grams load): 600-700

Coating porosity: <2%

### Coating roughness (Ra): 8.3 microns

### Example 2

In this example, HVOF spraying was used to deposit a single layered coating of a self-flux alloy onto a copper substrate. The HVOF process parameters for the coating are given below:

| Coating composition: | Ni—14Cr—4.7Fe—3.38B—4.43Si, wt. % | |
|---|---|---|
| HVOF system: | DJ-2700 | |
| Process parameters: | Oxygen pressure/flow: | 150 psi/24 scfh |
| | Fuel pressure/flow: | 100 psi/40 scfh |
| | Air pressure/flow: | 105 psi/58 scfh |
| | Distance: | 12″ |
| | Feed rate: | 5 lb/h |

The coating properties are listed below:

### Coating hardness (HV 300 grams load): 700-750

Coating porosity: <1%

### Coating roughness (Ra): 7.5 microns

### Example 3

In this example, HVOF spraying was used to deposit a single layered coating of WC/Co onto a copper substrate. The as-sprayed coating was ground and polished to reduce its surface roughness from about 4.5 microns to about 1.0 micron. It was then sealed with a sodium silicate solution comprising BN at a temperature of about 550° C. The HVOF process parameters for the coating are given below:

| Coating composition: | WC/12Co, wt. % | |
|---|---|---|
| HVOF system: | JP-5000 (commercially available from | |
| | Praxair-Tafa, US) | |
| Process parameters: | Oxygen flow: | 2000 scfh |
| | Fuel flow: | 6.0 gallons per hour (gph) |
| | Distance: | 13″ |
| | Feed rate: | 10 lb/h |

The coating properties are listed below:

### Coating hardness (HV at 300 grams load): 850-1050

Coating porosity: <1%

### Coating roughness (Ra): 4.5 microns

### Example 4

In this example, modified HVOF spraying of a liquid suspension comprising INCONEL® 625 particles of less than 11 microns in size was used to deposit a single layered coating onto a copper substrate along with AlN dispersed therein. The HVOF process parameters for the coating are given below:

| Coating composition: | INCONEL ® 625 + 10AlN, wt % | |
|---|---|---|
| HVOF system: | DJ-2700 | |
| Process parameters: | Oxygen pressure/flow: | 150 psi/24 scfh |
| | Fuel pressure/flow: | 100 psi/46 scfh |
| | Air pressure/flow: | 105 psi/48 scfh |
| | Distance: | 9″ |
| | Feed rate: | 80 grams/minute (g/min) |

The coating properties are listed below:

### Coating hardness (HV at 300 grams load): 650-750

Coating porosity: <1%

### Coating roughness (Ra): 3.5 microns

### Example 5

In this example, HVOF spraying was used to deposit a double layered coating comprising a bondcoat of Al and a topcoat of INCONEL® 625 onto a copper substrate. The HVOF process parameters for the coating are given below:

| HVOF system: | DJ-2700 (Sulzer-Metco, US) | |
|---|---|---|
| Process parameters: | Al bondcoat | |
| | Oxygen pressure/flow: | 150 psi/20 scfh |
| | Fuel pressure/flow: | 100 psi/40 scfh |
| | Air pressure/flow: | 105 psi/58 scfh |
| | Distance: | 12″ |
| | Feed rate: | 2 lb/h |
| Process parameters: | Inconel 625 topcoat | |
| | Oxygen pressure/flow: | 150 psi/24 scfh |
| | Fuel pressure/flow: | 100 psi/44 scfh |
| | Air pressure/flow: | 105 psi/48 scfh |
| | Distance: | 11″ |
| | Feed rate: | 5 lb/h |

The properties of the bondcoat and topcoat are listed below:

### Bondcoat

### Coating hardness (HV at 300 grams load): 150-200

Coating porosity: <1%

### Coating roughness (Ra): 7.5 microns

### Topcoat

### Coating hardness (HV at 300 grains load): 600-700

Coating porosity: <2%

### Coating roughness (Ra): 8.5 microns

### Example 6

In this example, HVOF spraying was used to deposit a double layered coating comprising a bondcoat of Al and a topcoat of a self-flux alloy onto a copper substrate. The HVOF process parameters for the coating are given below:

| Coating composition: | WC/12Co, wt. % | |
|---|---|---|
| HVOF system: | DJ-2700 | |
| Process parameters: | Al bondcoat | |
| | Oxygen pressure/flow: | 150 psi/20 scfh |
| | Fuel pressure/flow: | 100 psi/40 scfh |
| | Air pressure/flow: | 105 psi/58 scfh |
| | Distance: | 12″ |
| | Feed rate: | 2 lb/h |
| Process parameters: | Self-flux alloy topcoat | |
| | Oxygen pressure/flow: | 150 psi/24 scfh |
| | Fuel pressure/flow: | 100 psi/40 scfh |
| | Air pressure/flow: | 105 psi/58 scfh |
| | Distance: | 10″ |
| | Feed rate: | 5 lb/h |

The properties of the topcoat are listed below:

### Coating hardness (HV at 300 grams load): 700-750

Coating porosity: <1%

### Coating roughness (Ra): 8.0 microns

### Example 7

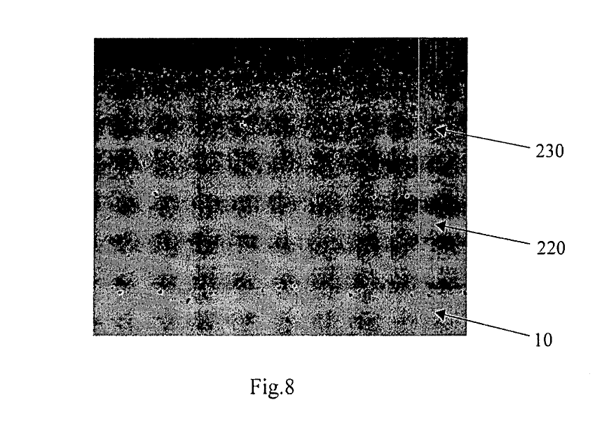

In this example, HVOF thermal spraying was used to deposit a double layered coating comprising a bondcoat layer of Ni and a topcoat layer of a self-flux alloy onto a copper substrate. FIG. 8 depicts an optical micrograph taken along the cross-section of the coated mold member, which shows the bondcoat layer 220 and the topcoat layer 230 disposed on the copper substrate 10. The bondcoat layer 220 and the topcoat layer 230 are fully dense and highly bonded to the copper substrate 10. A well-bonded interface exists between the bondcoat layer 220 and the topcoat layer 230. The HVOF process parameters for the coating are given below:

| Coating composition: | Ni—14.5Cr—4.5Fe—4.5Si—3.2B, | |
|---|---|---|
| | wt. % | |
| HVOF system: | JP-5000 | |
| Process parameters: | Ni bondcoat | |
| | Oxygen flow: | 1800 scfh |
| | Fuel flow: | 5.1 gph |
| | Distance: | 14″ |
| | Feed rate: | 10 lb/h |
| | Self-flux topcoat | |
| | Oxygen flow: | 1950 scfh |
| | Fuel flow: | 5.75 gph |
| | Distance: | 15″ |
| | Feed rate: | 10 lb/h |

The properties of the bondcoat and topcoat are listed below:

### Ni-bondcoat

### Coating hardness (HV at 300 grams load): 260-280

Coating porosity: <1%

### Coating roughness (Ra): 5.0 microns

### Self-Flux Topcoat

### Coating hardness (HV at 300 grams load): 750-825

Coating porosity: <1%

### Coating roughness (Ra): 8.5 microns

### Example 8

In this example, HVOF spraying was used to deposit a double layered coating comprising a bondcoat of Ni and a topcoat of a self-flux alloy and WC/Co onto a copper substrate. The HVOF process parameters for the coating are given below:

| Topcoat composition: | (Ni—14.5Cr—4.5Fe—4.5Si—3.2B) + | |
|---|---|---|
| | 10 (WC/12Co), wt. % | |
| HVOF system: | JP-5000 | |
| Process parameters: | Ni bondcoat | |
| | Oxygen flow: | 1800 scfh |
| | Fuel flow: | 5.1 gph |
| | Distance: | 14″ |
| | Feed rate: | 10 lb/h |
| | Self-flux topcoat | |
| | Oxygen flow: | 2000 scfh |
| | Fuel flow: | 5.85 gph |
| | Distance: | 15″ |
| | Feed rate: | 10 lb/h |

The properties of the composite topcoat are listed below:

### Coating hardness (HV at 300 grams load): 800-880

Coating porosity: <1%

### Coating roughness (Ra): 8.2 microns

### Example 9

In this example, electroplating was used to deposit a double layered coating comprising a bondcoat of Ni and a topcoat of a Ni/WC composite onto a Cu substrate.

The Cu substrate was sand blasted, degreased, neutralized, and activated. After activation, the Cu substrate was immersed into a nickel sulphamate bath where the anode was Ni and the cathode was the Cu substrate. An electrodeposition current was applied to the bath and monitored using an amperometer with an accuracy of 0.1 milliAmpere (mA) under a controlled temperature and acid concentration. The deposition parameters included: a plating ply of 2.7, a machine unit stirring value of 60, and a current density of 20 amperes/foot squared (A/ft²). The plating was performed at 20 to 50 A/ft². The thickness of the coating depended on the plating time.

After the first Ni layer was plated, the sample was quickly transferred into a Ni/WC plating bath. The sample was transferred when everything was ready to start plating (i.e., electrolyte up to temperature, stirrer on and out of the way of where the sample will be, hooks/suspension clips ready to receive the sample, power supply on and turned to a low value such as about 10% of the estimated plating current, etc.). A film of nickel electrolyte on the sample was maintained during the transfer to prevent air oxidation of the sample surface. The sample was immersed in the plating bath (i.e., electrolyte) such that all surfaces to be plated were below the electrolyte surface. The sample was kept well covered with electrolyte, and a good flow of electrolyte at and by the sample was maintained.

Once the sample was positioned satisfactorily, the plating current was slowly raised to as high as possible to help the electrophoresis effect on the WC nanoparticles that are deposited. The current was raised over a period of 15 to 30 seconds to the desired plating current. The plating time depended on the desired thickness of the plated layer. After plating, the current was reduced to about zero. The sample was then removed, washed, and inspected.

The resulting coating had a thickness ranging from a few microns to a few hundred microns and a coating hardness ranging from 400 to 900 HV. The volume fraction of the WC phase depended on the amount of WC particles dispersed into the bath at a given volume. It ranged from 10 g/L to 100 g/L concentration.

### Example 10

In this example, electroplating was used to deposit a double layered coating comprising a bondcoat of Ni and a topcoat of a Ni/Cr₂O₃ composite onto a Cu substrate.

The Cu substrate was sand blasted, degreased, neutralized, and activated. After activation, the Cu substrate was immersed into a nickel sulphamate bath where the anode was Ni and the cathode was the Cu substrate. An electrodeposition current was applied to the bath and monitored using an amperometer with an accuracy of 0.1 mA, under a controlled temperature and acid concentration. The deposition parameters included: a plating pH of 2.7, a machine unit stirring value of 60, and a current density of 20 A/ft². The plating was performed at 20 to 50 A/ft². The thickness of the coating depended on the plating time.

After the first Ni layer was plated, the sample was quickly transferred into a Ni/Cr₂O₃ plating bath. The sample was transferred when everything was ready to start plating (i.e., electrolyte up to temperature, stirrer on and out of the way of where the sample will be, hooks/suspension clips ready to receive the sample, power supply on and turned to a low value such as about 10% of the estimated plating current, etc.). A film of nickel electrolyte on the sample was maintained during the transfer to prevent air oxidation of the sample surface. The sample was immersed in the plating bath such that all surfaces to be plated were below the electrolyte surface. The sample was kept well covered with electrolyte, and a good flow of electrolyte at and by the sample was maintained.

Once the sample was positioned satisfactorily, the plating current was slowly raised to as high as possible to help the electrophoresis effect on the Cr₂O₃ nanoparticles that are deposited. The current was raised over a period of 15 to 30 seconds to the desired plating current. The plating time depended on the desired thickness of the plated layer. After plating, the current was reduced to about zero. The sample was then removed, washed, and inspected.

The topcoat layer was a composite coating of Ni/Cr₂O₃. The resulting had a thickness ranging from a few microns to a few hundred microns and a coating hardness ranging from 400 to 900 HV. The volume fraction of the Cr₂O₃ phase depended on the amount of Cr₂O₃ particles dispersed into the bath at a given volume. It ranged from 10 g/L to 100 g/L concentration.

### Example 11

In this example, electroplating was used to deposit a double layered coating comprising a bondcoat of Ni and a topcoat comprising BN particles dispersed in a Ni/Cr₂O₃ matrix onto a Cu substrate.

The Cu substrate was sand blasted, degreased, neutralized, and activated. After activation, the Cu substrate was immersed into a nickel sulphamate bath where the anode was Ni and the cathode was the Cu substrate. An electrodeposition current was applied to the bath and monitored using an amperometer with an accuracy of 0.1 mA, under a controlled temperature and acid concentration. The deposition parameters included: a plating pH of 2.7, a machine unit stirring value of 60, and a current density of 20 A/ft². The plating was performed at 20 to 50 A/ft². The thickness of the coating depended on the plating time.

After the first Ni layer was plated, the sample was quickly transferred into a BN/Cr₂O₃/Ni plating solution. The sample was transferred when everything was ready to start plating (i.e., electrolyte up to temperature, stirrer on and out of the way of where the sample will be, hooks/suspension clips ready to receive the sample, power supply on and turned to a low value such as about 10% of the estimated plating current, etc.). A film of nickel electrolyte on the sample was maintained during the transfer to prevent air oxidation of the sample surface. The sample was immersed in the plating bath such that all surfaces to be plated were below the electrolyte surface. The sample was kept well covered with electrolyte, and a good flow of electrolyte at and by the sample was maintained.

Once the sample was positioned satisfactorily, the plating current was slowly raised to as high as possible to help the electrophoresis effect on the Cr₂O₃ and BN nanoparticles. The current was raised over a period of 15 to 30 seconds to the desired plating current. The plating time depended on the desired thickness of the plated layer. After plating, the current was reduced to about zero. The sample was then removed, washed, and inspected.

The resulting coating had a thickness ranging from a few microns to a few hundred microns and a coating hardness ranging from 400 to 700 HV. The volume fraction of the BN+Cr₂O₃ phase depended on the amount of BN+Cr₂O₃ particles dispersed into the bath at a given volume. It ranged from 10 g/L to 100 g/L concentration.

### Example 12

In this example, electroplating was used to deposit a double layered coating comprising a bondcoat of Ni and a topcoat of a SiC/Ni composite onto a Cu substrate.

The Cu substrate was sand blasted, degreased, neutralized, and activated. After activation, the Cu substrate was immersed into a nickel sulphamate bath where the anode was Ni and the cathode was the CLl substrate. An electrodeposition current was applied to the bath and monitored using an amperometer with an accuracy of 0.1 mA, under a controlled temperature and acid concentration. The deposition parameters included: a plating pH of 2.7, a machine unit stirring value of 60, and a current density of 20 amp/ft². The plating was performed at 20 to 50 A/ft². The thickness of the coating depended on the plating time.

After the first Ni layer was plated, the sample was quickly transferred into a SiC/Ni plating solution to deposit a SiC/Ni composite layer on the Ni bondcoat layer. The sample was transferred when everything was ready to start plating (i.e., electrolyte up to temperature, stirrer on and out of the way of where the sample will be, hooks/suspension clips ready to receive the sample, power supply on and turned to a low value such as about 10% of the estimated plating current, etc.). A film of nickel electrolyte on the sample was maintained during the transfer to prevent air oxidation of the sample surface. The sample was immersed in the plating bath such that all surfaces to be plated were below the electrolyte surface. The sample was kept well covered with electrolyte, and a good flow of electrolyte at and by the sample was maintained.

Once the sample was positioned satisfactorily, the plating current was slowly raised to as high as possible to help the electrophoresis effect on the SiC nanoparticles. The current was raised over a period of 15 to 30 seconds to the desired plating current. The plating time depended oil the desired thickness of the plated layer. After plating, the current was reduced to about zero. The sample was then removed, washed, and inspected.

The resulting coating had a thickness ranging from a few microns to a few hundred microns and a coating hardness ranging from 400 to 900 HV. The volume traction of the SiC phase depended on the amount of SiC particles dispersed into the bath at a given volume. It ranged from 10 g/L to 100 g/L concentration.

### Example 13

In this example, electroplating was used to deposit a double layered coating comprising a bondcoat of Ni and a topcoat of a B₄C/Ni composite onto a Cu substrate.

The Cu substrate was sand blasted, degreased, neutralized, and activated. After activation, the Cu substrate was immersed into a nickel sulphamate bath where the anode was Ni and the cathode was the Cu substrate. An electrodeposition current was applied to the bath and monitored using an amperometer with an accuracy of 0.1 mA, under a controlled temperature and acid concentration. The deposition parameters included: a plating pH of 2.7, a machine unit stirring value of 60, and a current density of 20 A/ft². The plating was performed at 20 to 50 A/ft². The thickness of the coating depended on the plating time.

After the first Ni layer was plated, the sample was quickly transferred into a B₄C/Ni plating solution to deposit a B₄C/Ni composite layer on the Ni bondcoat layer. The sample was transferred when everything was ready to start plating (i.e., electrolyte up to temperature, stirrer on and out of the way of where the sample will be, hooks/suspension clips ready to receive the sample, power supply on and turned to a low value such as about 10% of the estimated plating current, etc.). A film of nickel electrolyte on the sample was maintained during the transfer to prevent air oxidation of the sample surface. The sample was immersed in the plating bath such that all surfaces to be plated were below the electrolyte surface. The sample was kept well covered with electrolyte, and a good flow of electrolyte at and by the sample was maintained.

Once the sample was positioned satisfactorily, the plating current was slowly raised to as high as possible to help the electrophoresis effect on the B₄C particles. The current was raised over a period of 15 to 30 seconds to the desired plating current. The plating time depended on the desired thickness of the plated layer. After plating, the current was reduced to about zero. The sample was then removed, washed, and inspected.

The resulting coating had a thickness ranging from a few microns to a few hundred microns and a coating hardness ranging from 400 to 900 HV. The volume fraction of the B₄C phase depended on the amount of B₄C particles dispersed into the bath at a given volume. It ranged from 10 g/L to 100 g/L concentration.

As used herein, the terms “a” and “an” do not denote a limitation of quantity but rather denote the presence of at least one of the referenced items. Moreover, the endpoints of all ranges directed to the same component or property are inclusive of the endpoint and independently combinable (e.g., “about 5 wt % to about 20 wt %,” is inclusive of the endpoints and all intermediate values of the ranges of about 5 wt % to about 20 wt %). Reference throughout the specification to “one embodiment”, “another embodiment”, “an embodiment”, and so forth means that a particular element (e.g., feature, structure, and/or characteristic) described in connection with the embodiment is included in at least one embodiment described herein, and might or might not be present in other embodiments, in addition, it is to be understood that the described elements may be combined in any suitable manner in the various embodiments. Unless defined otherwise, technical and scientific terms used herein have the same meaning as is commonly understood by one of skill in the art to which this invention belongs.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

1. A mold comprising:
a mold member comprising copper; and
a coating disposed on at least a portion of a surface of the mold member, wherein the coating has a coefficient of thermal expansion of about 10×10⁻⁶/° C. to about 16.5×10⁻⁶/° C. and a Vickers Hardness Number of greater than about 500 and less than about 1200 at a temperature of less than or equal to about 600° C.

2. The mold of claim 1, wherein the coating comprises a Fe-based alloy, Ni-based alloy, a Co-based alloy, Fe—Cr, Co—Cr, Ni—Cr, Ni—Al, Fe—Al, FeCrAl, NiCrAl, NiCrMo, NiCrSiB, NiCrAlY, CoCrAlY, or a combination comprising at least one of the foregoing.

3. The mold of claim 1, wherein the coating has a higher corrosion resistance and a higher erosion resistance than does copper.

4. The mold of claim 1, wherein the coating comprises a bondcoat layer above the surface of the mold member and a topcoat layer above the bondcoat layer, wherein the coefficient of thermal expansion of the topcoat layer is equivalent to or less than that of copper and the bondcoat layer, and wherein the Vickers Hardness Number of the topcoat layer is higher than that of copper and the bondcoat layer.

5. The mold of claim 4, wherein the coating further comprises an intermediate layer between the bondcoat layer and the topcoat layer, wherein the intermediate layer comprises a graded composition or a composite composition.

6. The mold of claim 1, wherein the coating comprises a graded composition or two or more layers, wherein the Vickers Hardness Number of the graded composition increases with distance from the surface, and wherein the Vickers Hardness Number of the two or more layers increase from one layer to the next in a direction away from the surface.

7. The mold of claim 1, wherein the coating further comprises a metallic matrix and superfine particles, nanoparticles, or both of the foregoing particles dispersed in the metallic matrix.

8. The mold of claim 7, wherein the particles comprise a lubricating additive, a thermally conductive additive, a hard additive, or a combination comprising at least one of the foregoing additives.

9. The mold of claim 8, wherein the lubricating additive comprises BN, MoSi₂, FeS, CaF₂, graphite, B₄C, or a combination comprising at least one of the foregoing.

10. The mold of claim 8, wherein the thermally conductive additive comprises WC, TiN, AlN, Si₃N₄, or a combination comprising at least one of the foregoing.

11. The mold of claim 8, wherein the hard additive comprises WC, Cr₂C₃, TiC, SiC, TiB₂, ZrB₂, or a combination comprising at least one of the foregoing.

12. The mold of claim 7, wherein the metallic matrix comprises Fe, Ni, Co, Co—Fe, Co—Ni, Co—B, Co—P, Fe—Ni, NiCr, NiCrAlY, NiCrBSi, or a combination comprising at least one of the foregoing.

13. The mold of claim 1, wherein the coating has a thickness of about 50 micrometers to about 3 millimeters.

14. The mold of claim 1, further comprising another coating disposed on a different portion of the surface of the mold member, wherein the coating and the another coating have different compositions.

15. The mold of claim 1, wherein the coating increases in thickness from an upper section to a lower section of the mold member.

16. A method of forming a coating on a surface of a mold, comprising: disposing a coating on at least a portion of a surface of a mold comprising copper, the coating having a coefficient of thermal expansion of about 10×10⁻⁶/° C. to about 16.5×10⁻⁶/° C. and a Vickers Hardness Number of greater than about 500 and less than about 1200 at a temperature of less than or equal to about 600° C.

17. The method of claim 16, wherein said disposing comprises thermal spraying, overlay welding, cladding, physical vapor deposition, or electroplating.

18. The method of claim 17, wherein the thermally sprayed coating is post treated by subjecting it to re-fusing, melting, sintering, sealing, or hot isostatic pressing.

19. The method of claim 16, further comprising machining the coating to a desired surface roughness, configuration, and coating thickness.

20. The method of claim 16, wherein the coating has a higher corrosion resistance and a higher erosion resistance than does copper.

21. The method of claim 16, wherein the coating comprises a bondcoat layer above the surface and a topcoat layer above the coating, wherein the coefficient of thermal expansion of the bondcoat layer is equivalent to or higher than that of the topcoat layer, and the Vickers Hardness Number of the bondcoat layer is lower than that of the topcoat layer.

22. The method of claim 21, wherein the coating further comprises an intermediate layer between the bondcoat layer and the topcoat layer, wherein the intermediate layer comprises a graded composition or a composite composition.

23. The method of claim 16, wherein the coating comprises a graded composition or two or more layers, wherein the Vickers Hardness Number of the graded composition increases with distance from the surface, and wherein the Vickers Hardness Number of the two or more layers increase from one layer to the next in a direction away from the surface.

24. The method of claim 16, wherein the coating further comprises a metallic matrix and superfine particles, nanoparticles, or both of the foregoing particles dispersed in the metallic matrix.

25. A method of casting a molten material, comprising: disposing a molten material in a mold comprising copper, wherein an interior surface of the mold is at least partially coated with a coating having a coefficient of thermal expansion of about 10×10⁻⁶/° C. to about 16.5×10⁻⁶/° C. and a Vickers Hardness Number of greater than about 500 and less than about 1200 at a temperature of less than or equal to about 600° C.

26. The method of claim 25, wherein the coating comprises a graded composition or two or more layers, wherein the Vickers Hardness Number of the graded composition increases with distance from the surface, and wherein the Vickers Hardness Number of the two or more layers increase from one layer to the next in a direction away from the surface.

27. The method of claim 25, wherein the coating further comprises a metallic matrix and superfine particles, nanoparticles, or both of the foregoing particles dispersed in the metallic matrix.

28. A mold comprising:
a mold member comprising copper; and
a coating disposed on at least a portion of a surface of the mold member, wherein the coating comprises a WC—Co alloy, a WC—CoCr alloy, a Ni—Cr₂C₃, a NiCr—Cr₂C₃ alloy, or a combination comprising at least one of the foregoing.
